(19) United States
(12) Patent Application Publication
(10) Pub. No.: US 2026/0343782 A1
(43) Pub. Date: Oct. 29, 2026

(54) FRONT ACCESSIBLE SLIDING PATCH PANEL ASSEMBLY

(71) Applicant: Panduit Corp., Tinley Park, IL (US)

(72) Inventor: Roman J. Churnovic, Manhattan, IL (US)

(73) Assignee: Panduit Corp., Tinley Park, IL (US)

(21) Appl. No.: 19/188,396

(22) Filed: Apr. 24, 2025

(51) Int. Cl. H05K 7/14; G02B 6/44

(52) U.S. Cl. CPC H05K 7/1492; G02B 6/4455

(57) ABSTRACT

A sliding patch panel assembly including a patch panel and locking brackets. The patch panel has a front member with a top, a bottom, a front, a back, a first end, and a second end. A first arm extends from the back of the first end of the front member and a second arm extends from the back of the second end of the front member. A flange extends away from the front member at the first end and at the second end. The locking brackets slidingly engaging the first arm and second arm. The locking brackets are releasably secured to the flanges to allow the front member to slide away from the locking brackets.

### FIELD OF THE INVENTION

The present invention relates to a patch panel, and more particularly to a front accessible sliding patch panel assembly.

### BACKGROUND OF THE INVENTION

High density 48 port mini-com 1RU (rack unit) patch panels are mounted to racks or in cabinets in a data center. Patch panels have been designed to accept all mini-com modules for UTP, STP, A/V or select fiber. High density patch panels are used for multi-media applications. High density patch panels allow cables to flow to sides of the rack, minimizing the need for horizontal cable managers and increasing the density of the rack space. However, when the high density 1 RU patch panel is positioned between two switches in a cabinet or rack configuration, it is often difficult to access the rear of the patch panel ports and the jacks installed in the patch panel for moves, adds, and changes, when necessary.

There is a need for a high density 48 port mini-com 1 RU patch panel assembly that can be accessed and altered from the front of the cabinet or the front of a rack for easy moves, adds, and changes of the jacks and the cabling installed in the patch panel assembly.

### SUMMARY OF THE INVENTION

A sliding patch panel assembly is installed in a communication system. The sliding patch panel assembly includes a patch panel and locking brackets. The patch panel has a front member with a top, a bottom, a front, a back, a first end, and a second end. A first arm extends from the back of the first end of the front member and a second arm extends from the back of the second end of the front member. Flanges extend away from the front member at the first end and at the second end. The locking brackets slidingly engage the first arm and second arm of the patch panel. The locking brackets are releasably secured to the flanges extending from the first end and the second end of the front member of the patch panel to allow the front member to slide away from the locking brackets.

### BRIEF DESCRIPTION OF THE DRAWINGS

FIG. 1 is a perspective view of the front accessible sliding patch panel assembly of the present invention.

FIG. 2 is an exploded view of the front accessible sliding patch panel assembly of FIG. 1.

FIG. 3 is a perspective view of the front accessible sliding patch panel assembly of FIG. 1.

FIG. 4 is a perspective view of the front accessible sliding patch panel assembly of FIG. 1 in an extended position.

### DETAILED DESCRIPTION

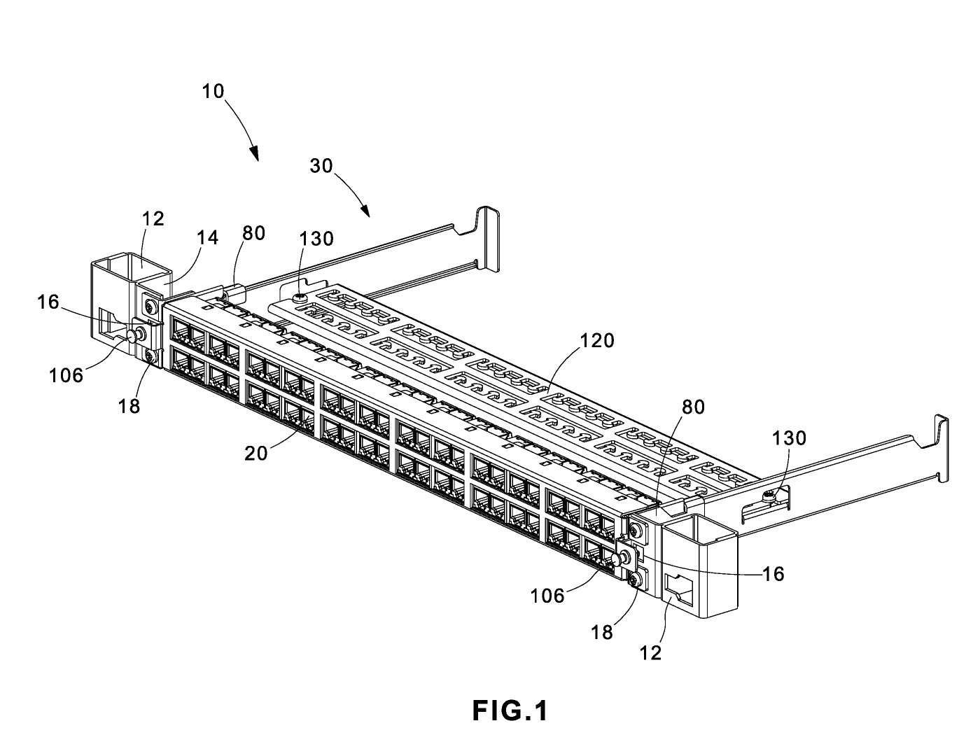

FIG. 1 illustrates a partial view of a communication system 10 that includes support rails 12, mounting screws 18, jacks 20, and a sliding patch panel assembly 30. Although not illustrated, the communication system may also include cabinets, racks, cable management, overhead cable routing systems, horizontal cabling, and other similar equipment located in a datacenter. For clarity, FIG. 1 illustrates only a small section of two support rails 12. The support rails 12 are depicted as a typical equipment rail found in a datacenter cabinet but can be any variety of rail or post designed to hold passive or active equipment. The support rails 12 are generally rectangular with a flange 14 extending the length of the rail. The flange 14 has a plurality of openings 16 extending the length of the rail.

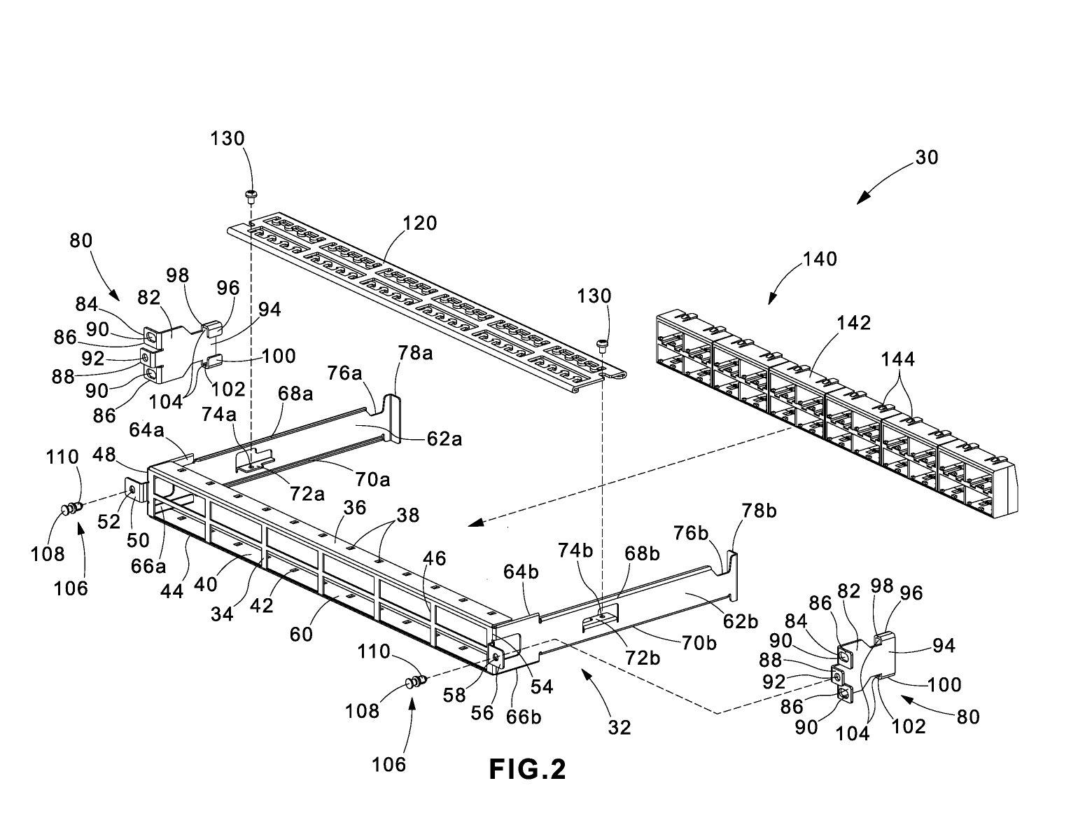

FIG. 2 is an exploded view of the sliding patch panel assembly 30. The sliding patch panel assembly 30 includes a patch panel 32, locking brackets 80, press latches 106, a strain relief panel 120, low profile screws 130, and jack inserts 140. The patch panel 32 includes a front member 34 with a top 36, a bottom 40, a front 44, a back 46, a first end 48, a second end 54, and a plurality of openings 60. A first arm 62a extends from the back of the first end and a second arm 62b extends from the back of the second end. The first arm 62a and the second arm 62b are parallel to each other. The top 36 and bottom 40 of the front member 34 include a plurality of pockets 38, 42, respectively, for receiving latches 144 extending from the jack inserts 140. The first end 48 of the front member 34 and the second end 54 of the front member 34 each include a flange 50, 56, respectively, extending away from the front member 34. Each flange 50, 56 includes a hole 52, 58, respectively, for receiving the press latches 106 to releasably secure the patch panel 32 to the locking brackets 80.

The first arm 62a includes a top flange 64a, a bottom flange 66a, a top slide rail 68a, a bottom slide rail 70a, a support flange 72a, a notch 76a, and an end flange 78a. The second arm 62b includes a top flange 64b, a bottom flange 66b, a top slide rail 68b, a bottom slide rail 70b, a support flange 72b, a notch 76b, and an end flange 78b. The support flange 72a of the first arm 62a and the support flange 72b of the second arm 62b extend inwards towards each other. Each support flange 72a, 72bincludes a threaded hole 74a, 74b, respectively, for receiving a fastener, such as a low profile screw 130, to secure the strain relief panel 120 to the patch panel 32. The strain relief panel 120 is designed to allow the cables terminated in the jacks to be secured with cable ties to better address cable management concerns.

The locking brackets 80 include a main member 82 with a front end 84 and a back end 94. The front end 84 includes flanges 86, 88. The flanges 86, 88 are parallel to each other. Each flange 86, 88 includes an opening 90, 92, respectively, for receiving a fastener.

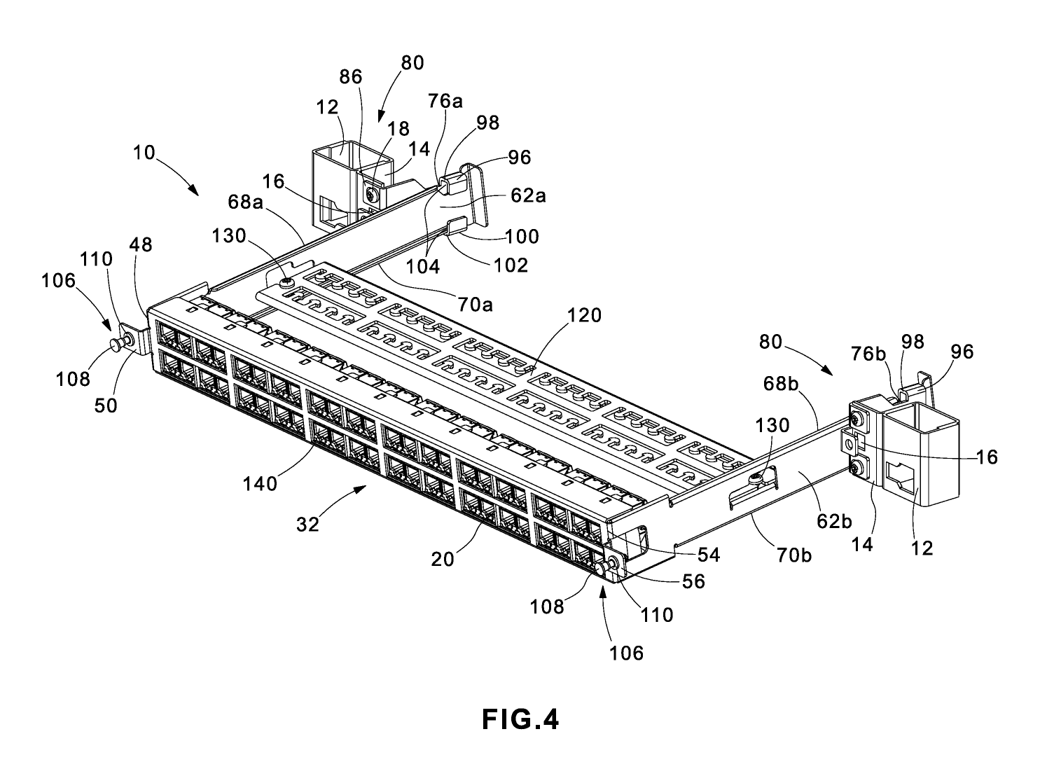

The back end 94 includes a top L-shaped projection 96 and a bottom L shaped projection 100. The top and bottom L shaped projections 96, 100 of each locking bracket 80 define a channel 104 therebetween. The top and bottom L shaped projections 96, 100 include edges 98, 102, respectively, designed to engage the flanges 64a, 66a, 64b, and 66b, of the first and second arms 62a, 62b of the patch panel 32 when the patch panel 32 is in an installed position (FIG. 1). The edges 98, 102 of the top and bottom L shaped projections 96, 100 are also designed to engage the notches 76a, 76b in the first and second arms 62a, 62b of the patch panel 32 when the patch panel 32 is in an extended position (see FIG. 4).

The press latch 106 of the patch panel assembly 30 includes a plunger 108 at one end and a grommet 110 at the opposite end. The plunger 108 is designed to be easily grabbed by the end user when it is desirable to release the patch panel 32 to enable the patch panel 32 to slide to an extended position with respect to the cabinet or rack (see FIG. 4).

The jack inserts 140 are designed to receive and house jacks 20. The jack inserts 140 include a plurality of latches 144 along the top 142 of the jack inserts 140. When the jack inserts 140 are installed in the front member 34 of the patch panel 32, the latches 144 engage the pockets 38 in the top 36 of the front member 34 to secure the jack inserts 140 to the patch panel 32.

As described below, the patch panel 32 is secured to the locking brackets 80 with the press latches 106. The locking brackets 80 of the sliding patch panel assembly 30 are secured to the support rails 12 via mounting screws 18 or other similar fasteners.

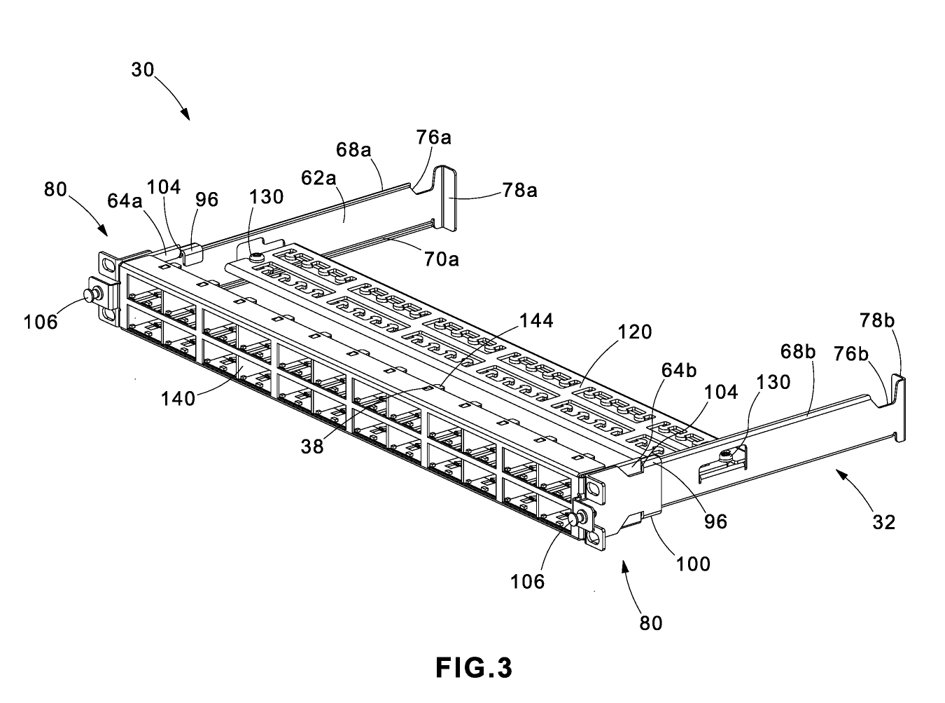

FIG. 3 is a perspective view of the assembled sliding patch panel assembly 30. FIG. 4 illustrates the communication system 10 with the sliding patch panel assembly 30 in a fully extended position. To slide the patch panel assembly 30, the plungers 108 of the press latches 106 are pulled to release the grommets 110 at the opposite end, which allows the patch panel 32 to detach from the locking brackets 80. The slide rails 68a, 70aof the first arm 62a and the slide rails 68b, 70b of the second arm 62b of the patch panel 32 glide through the channels 104 of the locking brackets 80 as the patch panel 32 is pulled forward to allow access to the rear of the patch panel 32 and the jacks 20 installed therein. When the sliding patch panel assembly 30 is in its fully extended position, the notch 76a in the first arm 62a and the notch 76b in the second arm 62b of the patch panel 32 engage the edges 98, 102 of the L-shaped projections 96, 100 of the locking bracket 80 to allow the patch panel 32 to pitch slightly downward thereby providing accessibility to the jacks 20 as well as strain relief panel 120 installed between the first arm 62a and the second arm 62b.

Once the jacks 20 and cable (not illustrated) have been moved, added, or changed, the patch panel 32 is slid back into positioned between the support rails 12 (see FIG. 1).

The channels 104 of the locking brackets 80 pass over the notches 76a, 76b in the arms 62a, 62b of the patch panel 32. The locking brackets 80 slide forward over the slide rails 68a, 70a, 68b, 70 b until the edges of the L shaped projections 96, 100 of the locking brackets 80 contact the flanges 64a, 66a, 64b, 66b of the patch panel 32. The openings 90 in the flanges 86 of the locking brackets 80 are aligned with the openings 16 in the flange 14 of the support rail 12. Mounting screws 18 are installed in the aligned openings 90 of the flanges 86 of the locking bracket 80 and the openings 16 in the flange 14 of the support rail 12 to secure the locking brackets 80 to the support rail. The opening 92 in the flange 88 of the looking brackets 80 is aligned with the holes 52, 58 in the flanges 50, 56, respectively, extending from the front member 34 of the patch panel 32. Press latches 106 are placed into the holes 52, 58 in the flanges 50, 56 of the patch panel 32 and the openings 92 in the flanges 88 of the locking brackets 80. The plungers 108 of the press latches 106 are then pressed inward to expand the grommets 110 at the opposite end of the press latches 106 to secure the patch panel 32 to the locking brackets 80.

The high density 48 port Mini-Com 1 RU sliding patch panel assembly of the present invention allows the user to access the back of the patch panel and the jacks installed therein from the front of the cabinet. As a result, the jacks installed in the patch panel are easily accessible for any moves, adds, and changes that are required within the cabinet.

Furthermore, while the particular preferred embodiments of the present invention have been shown and described, it will be obvious to those skilled in the art that changes and modifications may be made without departing from the teaching of the invention. The matter set forth in the foregoing description and accompanying drawings is offered by way of illustration only and not as limitation. The actual scope of the invention is intended to be defined in the following claims when viewed in their proper perspective based on the prior art.

What is claimed is:

1. A sliding patch panel assembly comprising:
a patch panel with a front member having a top, a bottom, a front, a back, a first end, and a second end;
a first arm extending from the back of the first end of the front member and a second arm extending from the back of the second end of the front member;
flanges extending away from the front member at the first end and at the second end, each flange includes a hole; and
locking brackets slidingly engaging the first arm and second arm, whereby the locking brackets are releasably secured to the flanges extending from the first end and the second end of the front member of the patch panel to allow the front member to slide away from the locking brackets.

2. The sliding patch panel assembly of claim 1, wherein the locking brackets include a main member with a front end and a back end, the back end has a top L shaped projection and a bottom L shaped projection, the top L shaped projection and the bottom L shaped projection define a channel therebetween.

3. The sliding patch panel assembly of claim 2, wherein the front end of the locking brackets include a plurality of flanges with openings for receiving fasteners to secure the locking brackets.

4. The sliding patch panel assembly of claim 3, wherein press latches releasably secure the locking brackets to the patch panel.

5. The sliding patch panel assembly of claim 4, wherein each press latch includes a plunger and a grommet opposite the plunger.

6. The sliding patch panel assembly of claim 1, wherein the first arm has a top flange and a bottom flange and the second arm has a top flange and a bottom flange; the top flanges and the bottom flanges provide a stop for the locking brackets.

7. The sliding patch panel assembly of claim 1, wherein the first arm has a top slide rail and a bottom slide rail and the second arm has a top slide rail and a bottom slide rail, whereby the locking brackets slide along the top slide rail and bottom slide rail of the first arm and the top slide rail and bottom slide rail of the second arm.

8. The sliding patch panel assembly of claim 1, wherein the first arm includes a notch and the second arm includes a notch, whereby the notch in the first arm receives one of the locking brackets when the patch panel is extended and the notch in the second arm receives one of the locking brackets when the patch panel is extended.

9. The sliding patch panel assembly of claim 1, wherein the front member having a plurality of openings.

10. The sliding patch panel assembly of claim 1, wherein the first arm and the second arm are parallel to each other.

11. The sliding patch panel assembly of claim 1, wherein the top of the front member includes pockets for receiving latches of a jack insert.

12. The sliding patch panel assembly of claim 1, further comprising a strain relief panel, the strain relief panel extends between the first arm and the second arm of the patch panel.

13. The sliding patch panel assembly of claim 12, wherein the first arm has a support flange with a hole and the second arm has a support flange with a hole, wherein one end of the strain relief panel is secured to the support flange extending from the first arm and an opposite end of the strain relief panel is secured to the support flange extending from the second arm.

14. The sliding patch panel assembly of claim 1, further comprising jack inserts with latches adapted to be secured to the front member of the patch panel.

15. A communication system comprising:
support rails; and
a sliding patch panel assembly secured to the support rails, the sliding patch panel assembly having a patch panel with a front member having a top, a bottom, a front, a back, a first end, and a second end; a first arm extending from the back of the first end of the front member and a second arm extending from the back of the second end of the front member; flanges extending away from the front member at the first end and at the second end, each flange includes a hole; and locking brackets slidingly engaging the first arm and second arm, whereby the locking brackets are releasably secured to the flanges extending from the first end and the second end of the front member of the patch panel to allow the front member to slide away from the locking brackets.

16. The communication system of claim 15, wherein the locking brackets include a main member with a front end and a back end, the back end has a top L shaped projection and a bottom L shaped projection, the top L shaped projection and the bottom L shaped projection define a channel therebetween.

17. The communication system of claim 16, wherein the front end of the locking brackets include a plurality of flanges with openings for receiving fasteners to secure the locking brackets.

18. The communication system of claim 15, wherein the first arm has a top flange and a bottom flange and the second arm has a top flange and a bottom flange; the top flanges and the bottom flanges provide a stop for the locking brackets.

19. The communication system of claim 15, wherein the first arm has a top slide rail and a bottom slide rail and the second arm has a top slide rail and a bottom slide rail, whereby the locking brackets slide along the top slide rail and bottom slide rail of the first arm and the top slide rail and bottom slide rail of the second arm.

20. The communication system of claim 15, wherein the first arm includes a notch and the second arm includes a notch, whereby the notch in the first arm receives one of the locking brackets when the patch panel is extended and the notch in the second arm receives one of the locking brackets when the patch panel is extended.
